(19) United States
(12) Patent Application Publication
(10) Pub. No.: US 2025/0364781 A1
(43) Pub. Date: Nov. 27, 2025

(54) Optical Device

(71) Applicant: Nippon Telegraph and Telephone Corporation, Tokyo (JP)

(72) Inventors: Hidetaka Nishi, Musashino-shi, Tokyo (JP); Shinji Matsuo, Musashino-shi, Tokyo (JP)

(21) Appl. No.: 18/868,048

(22) PCT Filed: May 27, 2022
(86) PCT No.: PCT/JP2022/021733

§ 371 Date: Nov. 21, 2024

(51) Int. Cl. H01S 5/026; H01S 5/125; H01S 5/22

(52) U.S. Cl. CPC H01S 5/026; H01S 5/125; H01S 5/22

(57) ABSTRACT

The optical device includes a gain region constituting a waveguide type semiconductor laser, and a waveguide type light modulation region that modulates laser light of the semiconductor laser. The semiconductor laser is a distributed Bragg reflector laser, and the gain region is disposed between a first distributed Bragg reflector region and a second distributed Bragg reflector region. Further, the light modulation region is disposed between the gain region and the first distributed Bragg reflector region. The light modulation region includes a light modulation layer including a material having an electro-optical effect and disposed in a range couplable to propagating light.

### DESCRIPTION

### Technical Field

The present invention relates to an optical device that modulates a frequency of emitted laser light.

### Background Art

In order to support continuously increasing information communication traffic, an increase in speed and capacity of optical communication devices and an increase in transmission distance have been dramatically advanced. Among optical communication devices, an optical transmitter is a key device that supports optical communication, and in particular, a directly modulated laser (DML) and an electro-absorption modulator integrated distributed feedback laser (EA-DFB) are widely used in an intensity modulation-direct detection (IMDD) transmission system that has a simpler system configuration. However, because DML and EA-DFB inherently generate frequency chirp, there has been a major problem in that the transmission distance is limited, especially now that transmission capacities of 100 Gbit/s/λ class have been achieved.

In response to the above-described problem, a frequency-modulated laser has been proposed as a device that solves the problem of frequency chirp and has excellent manufacturability because of having a device structure similar to DML and EA-DFB (Non Patent Literature 1). FIG. 13 illustrates a structure of the frequency-modulated laser. The frequency-modulated laser is a distributed Bragg reflector (DBR) laser, and includes a gain region 702 and a phase shift region 703 of an effective refractive index of a propagating light mode in a resonance region between two distributed Bragg reflector regions 701a and 701b. By modulating the effective refractive index of the phase shift region 703, a longitudinal mode starting wavelength of the DBR laser, that is, oscillation frequency is modulated.

The signal light frequency-modulated in the above-described frequency-modulated laser can then be transmitted through a simple optical filter to perform frequency-modulation-intensity modulation (FM-AM) conversion, and can also be applied to an IMDD system.

In addition, Non Patent Literature 2 also shows that this frequency-modulated laser can operate at a high speed unlike DML whose operation low range is largely limited by a relaxation vibration frequency.

### CITATION LIST

### Non Patent Literature

Non Patent Literature 1: S. Matsuo et al., “Extended Transmission Reach Using Optical Filtering of Frequency-Modulated Widely Tunable SSG-DBR Laser”, IEEE Photonics Technology Letters, vol. 20, no. 4, pp. 294-296, 2008.

Non Patent Literature 2: T. Kakitsuka and S. MATSUO, “High-Speed Frequency Modulated DBR Lasers for Long-Reach Transmission”, IEICE Transactions on Electronics, vol. E92.C, no. 7, p. 929, 2009.

Non Patent Literature 3: S. Matsuo and T. Kakitsuka, “Low-operating-energy directly modulated lasers for shortdistance optical interconnects”, Advances in Optics and Photonics, vol. 10, no. 3, pp. 567-643, 2018

### SUMMARY OF INVENTION

### Technical Problem

However, the above-described technology has the following problems. In the prior art, when a modulation electric field is applied to the phase shift region, even if a band gap is controlled so that intensity modulation due to the quantum confined Stark effect or the Franz-Keldysh effect does not occur, there is a problem that the intensity modulation occurs for some reason (for example, carriers flowing in and out of the phase shift region) and the operation speed decreases.

The present invention has been made to solve the above problems, and it is an object thereof to modulate a frequency by suppressing intensity modulation.

### Solution to Problem

An optical device according to the present invention

includes a gain region constituting a waveguide type semiconductor laser, and a waveguide type light modulation region that modulates laser light of the semiconductor laser, wherein the light modulation region includes a light modulation layer including a material having an electro-optical effect and disposed in a range couplable to propagating light, and a frequency of laser light oscillated by the semiconductor laser is modulated by modulating an effective refractive index of a propagating light mode by applying a modulation electric field to the light modulation layer.

### Advantageous Effects of Invention

According to the present invention, since the light modulation region is made of the material having the electro-optical effect as described above, it is possible to modulate the frequency while suppressing the intensity modulation.

### BRIEF DESCRIPTION OF DRAWINGS

FIG. 1A is a plan view illustrating a configuration of an optical device according to a first embodiment of the present invention.

FIG. 1B is a cross-sectional view illustrating a partial configuration of the optical device according to the first embodiment of the present invention.

FIG. 1C is a cross-sectional view illustrating a partial configuration of the optical device according to the first embodiment of the present invention.

FIG. 1D is a cross-sectional view illustrating a partial configuration of the optical device according to the first embodiment of the present invention.

FIG. 2A is a distribution diagram illustrating electromagnetic field distribution of a light propagation mode of the optical device according to the first embodiment of the present invention.

FIG. 2B is a distribution diagram illustrating electromagnetic field distribution of a light propagation mode of the optical device according to the first embodiment of the present invention.

FIG. 2C is a distribution diagram illustrating electromagnetic field distribution of a light propagation mode of the optical device according to the first embodiment of the present invention.

FIG. 3A is a plan view illustrating a configuration of an optical device according to a second embodiment of the present invention.

FIG. 3B is a cross-sectional view illustrating a partial configuration of the optical device according to the second embodiment of the present invention.

FIG. 3C is a cross-sectional view illustrating a partial configuration of the optical device according to the second embodiment of the present invention.

FIG. 3D is a cross-sectional view illustrating a partial configuration of the optical device according to the second embodiment of the present invention.

FIG. 4A is a distribution diagram illustrating electromagnetic field distribution of a light propagation mode of the optical device according to the second embodiment of the present invention.

FIG. 4B is a distribution diagram illustrating electromagnetic field distribution of a light propagation mode of the optical device according to the second embodiment of the present invention.

FIG. 4C is a distribution diagram illustrating electromagnetic field distribution of a light propagation mode of the optical device according to the second embodiment of the present invention.

FIG. 5A is a plan view illustrating a configuration of an optical device according to a third embodiment of the present invention.

FIG. 5B is a cross-sectional view illustrating a partial configuration of the optical device according to the third embodiment of the present invention.

FIG. 5C is a cross-sectional view illustrating a partial configuration of the optical device according to the third embodiment of the present invention.

FIG. 5D is a cross-sectional view illustrating a partial configuration of the optical device according to the third embodiment of the present invention.

FIG. 6A is a distribution diagram illustrating electromagnetic field distribution of a light propagation mode of the optical device according to the third embodiment of the present invention.

FIG. 6B is a distribution diagram illustrating electromagnetic field distribution of a light propagation mode of the optical device according to the third embodiment of the present invention.

FIG. 6C is a distribution diagram illustrating electromagnetic field distribution of a light propagation mode of the optical device according to the third embodiment of the present invention.

FIG. 7A is a plan view illustrating a configuration of an optical device according to a fourth embodiment of the present invention.

FIG. 7B is a cross-sectional view illustrating a partial configuration of the optical device according to the fourth embodiment of the present invention.

FIG. 7C is a cross-sectional view illustrating a partial configuration of the optical device according to the fourth embodiment of the present invention.

FIG. 7D is a cross-sectional view illustrating a partial configuration of the optical device according to the fourth embodiment of the present invention.

FIG. 8A is a distribution diagram illustrating electromagnetic field distribution of a light propagation mode of the optical device according to the fourth embodiment of the present invention.

FIG. 8B is a distribution diagram illustrating electromagnetic field distribution of a light propagation mode of the optical device according to the fourth embodiment of the present invention.

FIG. 8C is a distribution diagram illustrating electromagnetic field distribution of a light propagation mode of the optical device according to the fourth embodiment of the present invention.

FIG. 9A is a plan view illustrating a configuration of an optical device according to a fifth embodiment of the present invention.

FIG. 9B is a cross-sectional view illustrating a partial configuration of the optical device according to the fifth embodiment of the present invention.

FIG. 9C is a cross-sectional view illustrating a partial configuration of the optical device according to the fifth embodiment of the present invention.

FIG. 9D is a cross-sectional view illustrating a partial configuration of the optical device according to the fifth embodiment of the present invention.

FIG. 10A is a distribution diagram illustrating electromagnetic field distribution of a light propagation mode of the optical device according to the fifth embodiment of the present invention.

FIG. 10B is a distribution diagram illustrating electromagnetic field distribution of a light propagation mode of the optical device according to the fifth embodiment of the present invention.

FIG. 10C is a distribution diagram illustrating electromagnetic field distribution of a light propagation mode of the optical device according to the fifth embodiment of the present invention.

FIG. 11A is a plan view illustrating a configuration of an optical device according to a sixth embodiment of the present invention.

FIG. 11B is a cross-sectional view illustrating a partial configuration of the optical device according to the sixth embodiment of the present invention.

FIG. 11C is a cross-sectional view illustrating a partial configuration of the optical device according to the sixth embodiment of the present invention.

FIG. 12A is a distribution diagram illustrating electromagnetic field distribution of a light propagation mode of the optical device according to the sixth embodiment of the present invention.

FIG. 12B is a distribution diagram illustrating electromagnetic field distribution of a light propagation mode of the optical device according to the sixth embodiment of the present invention.

FIG. 13 is a cross-sectional view illustrating a structure of a frequency-modulated laser.

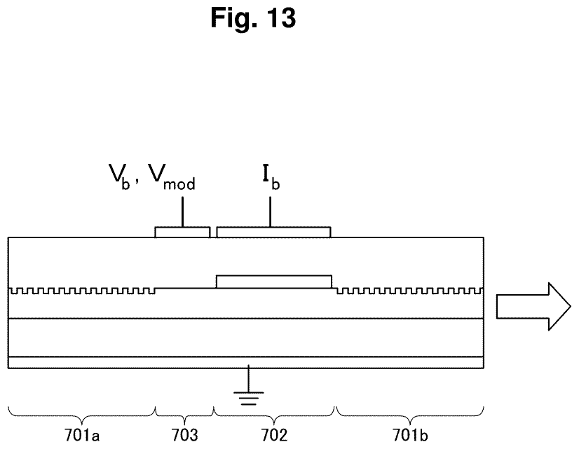

### DESCRIPTION OF EMBODIMENTS

The following is a description of optical devices according to embodiments of the present invention.

### First Embodiment

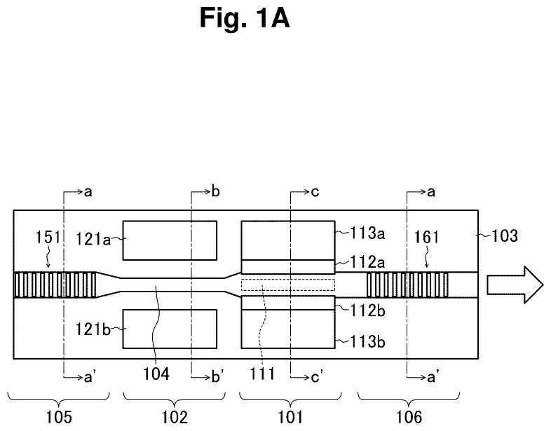

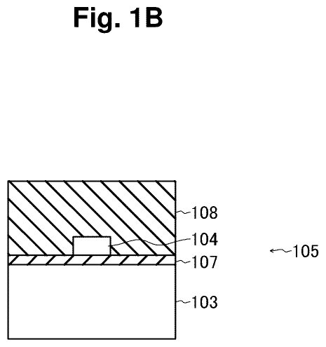

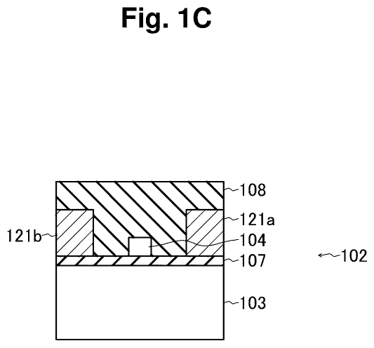

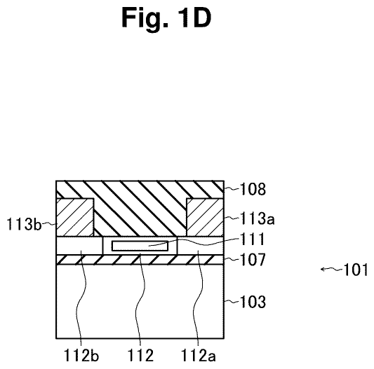

First, a configuration of an optical device according to a first embodiment of the present invention will be described with reference to FIGS. 1A, 1B, 1C, and 1D. FIG. 1B illustrates a cross section perpendicular to a waveguide direction along line aa′ in FIG. 1A. FIG. 1C illustrates a cross section perpendicular to the waveguide direction along line bb′ in FIG. 1A. FIG. 1D illustrates a cross section perpendicular to the waveguide direction along line cc′ in FIG. 1A. The optical device includes a gain region 101 constituting a waveguide type semiconductor laser, and a waveguide type light modulation region 102 that modulates laser light of the semiconductor laser.

In the first embodiment, the semiconductor laser is a distributed Bragg reflector laser, and the gain region 101 is disposed between a first distributed Bragg reflector region 105 and a second distributed Bragg reflector region 106. Further, the light modulation region 102 is disposed between the gain region 101 and the first distributed Bragg reflector region 105. The laser is oscillated (output) in the direction of the arrow illustrated in FIG. 1A.

The gain region 101 includes a p-type semiconductor layer 112a, an i-type semiconductor layer 112, and an n-type semiconductor layer 112b, and an active layer 111 is embedded in the i-type semiconductor layer 112. The p-type semiconductor layer 112a, the i-type semiconductor layer 112, and the n-type semiconductor layer 112b can include, for example, a group III-V compound semiconductor such as InP. By introducing predetermined impurities into the semiconductor layer, the p-type semiconductor layer 112a and the n-type semiconductor layer 112b can be formed. The semiconductor layer in which the p-type semiconductor layer 112a, the i-type semiconductor layer 112, and the n-type semiconductor layer 112b are formed can be formed on a light modulation layer 103 via a joining layer 107 including SiO₂, for example.

In addition, the active layer 111 can include InGaAlAs. Further, the active layer 111 can have a multiple quantum well structure. A structure is employed in which a current is injected in a direction (lateral direction) intersecting (perpendicular to) the waveguide direction with respect to the i-type semiconductor layer 112 via the p-type semiconductor layer 112a and the n-type semiconductor layer 112b using a p-electrode 113a and an n-electrode 113b (Reference Literature 1).

The light modulation region 102 includes the light modulation layer 103 including the material having the electro-optical effect and disposed in a range couplable to the propagating light. The frequency of the laser light oscillated by the semiconductor laser is modulated by modulating an effective refractive index of the propagating light mode by applying a modulation electric field to the light modulation layer 103 using an electrode 121a and an electrode 121b. The light modulation region 102 can include, for example, lithium niobate (LN).

In addition, the light modulation region 102 includes a core 104 formed on the light modulation layer 103 via the joining layer 107. The core 104 is formed continuously with the i-type semiconductor layer 112 (active layer 111) in the gain region 101. The electrode 121a and the electrode 121b are disposed with the core 104 interposed therebetween. The core 104 can include, for example, a group III-V compound semiconductor such as InP.

The first distributed Bragg reflector region 105 and the second distributed Bragg reflector region 106 include the core 104 formed on the light modulation layer 103 via the joining layer 107. The core 104 is continuously formed from the light modulation region 102 to the first distributed Bragg reflector region 105. In addition, the core width of the light modulation region 102 is small. Further, in the first distributed Bragg reflector region 105, a diffraction grating 151 is formed on the core 104. Similarly, in the second distributed Bragg reflector region 106, a diffraction grating 161 is formed on the core 104. The diffraction grating 151 and the diffraction grating 161 can also be formed on a side surface of the core 104.

In the first embodiment, the light modulation layer 103 and the joining layer 107 are formed in common over the entire region of the gain region 101, the light modulation region 102, the first distributed Bragg reflector region 105, and the second distributed Bragg reflector region 106, and the light modulation layer 103 also functions as a lower cladding. In addition, an upper cladding layer 108 including, for example, SiO₂ is formed over the entire region of the gain region 101, the light modulation region 102, the first distributed Bragg reflector region 105, and the second distributed Bragg reflector region 106. In addition, the gain region 101 can have a length of 80 μm in the waveguide direction, and the light modulation region 102 can have a length of 40 μm in the waveguide direction. Further, the first distributed Bragg reflector region 105 and the second distributed Bragg reflector region 106 can have a length of 80 μm in the waveguide direction.

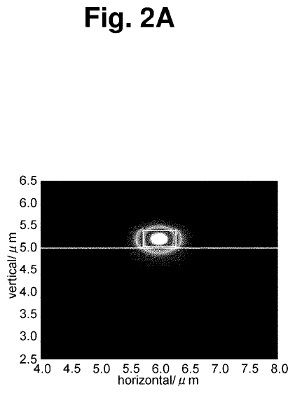

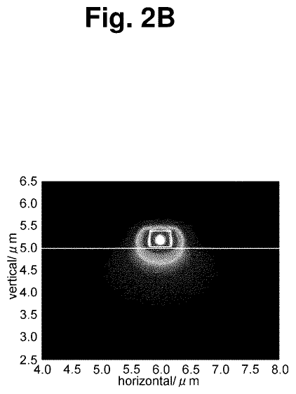

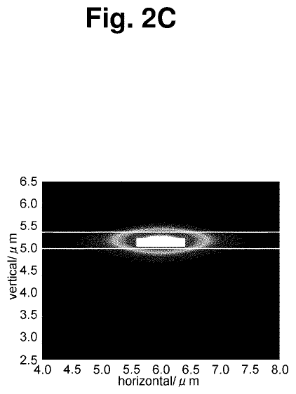

Next, a light propagation mode in the optical device according to the first embodiment will be described with reference to FIGS. 2A, 2B, and 2C.

First, FIG. 2A illustrates a light propagation mode of the first distributed Bragg reflector region 105 (second distributed Bragg reflector region 106). The core 104 in the first distributed Bragg reflector region 105 has a width of 600 nm and a height of 350 nm, and the joining layer 107 has a thickness of 20 nm. As illustrated in FIG. 2A, light is substantially confined in the core 104.

Next, FIG. 2B illustrates a light propagation mode of the light modulation region 102. The core 104 in the light modulation region 102 has a width of 350 nm and a height of 350 nm, and the joining layer 107 has a thickness of 20 nm. As illustrated in FIG. 2B, a part of the light confined in the core 104 leaks into the light modulation layer 103.

In the light modulation region 102, it is important to appropriately adjust the size of the cross section of the core 104 so that the electromagnetic field distribution of the propagating light mode leaks to the light modulation layer 103. When a modulation electric field is applied from the electrodes 121a and 121b disposed on the left and right of the core 104, a refractive index in the light modulation layer 103 is mainly modulated by the electro-optical effect. Thus, the effective refractive index of the propagating light mode in the light modulation region 102 is modulated. The size of the cross section of the core 104, the thickness of the joining layer 107, and the relative positions of the electrode 121a and the electrode 121b with respect to the core 104 are appropriately adjusted so as to obtain an effective refractive index change as large as possible with respect to the applied voltage.

Next, FIG. 2C illustrates a light propagation mode of the gain region 101. The thickness of the semiconductor layer in which the p-type semiconductor layer 112a, the i-type semiconductor layer 112, and the n-type semiconductor layer 112b are formed is 350 nm, the width of the active layer 111 is 800 nm, and the thickness of the active layer 111 is 250 nm. Further, the joining layer 107 had a thickness of 20 nm. As illustrated in FIG. 2C, light is tightly confined within the active layer 111.

Since the light modulation region 102 (light modulation layer 103) is made of the material having the electro-optical effect as described above, it is possible to modulate the frequency while suppressing the intensity modulation. Note that, as for the size of the core 104, in consideration of productivity, it is desirable to make the core height (thickness) equal to the thickness of the i-type semiconductor layer 112 in the gain region 101 as described above. It is desirable that the core width is appropriately adjusted in each region so that desired optical confinement in the core 104 is obtained within this condition, and the regions are connected by a tapered structure in which the width is gradually changed so as not to cause optical radiation loss and reflection.

In addition, a small optical transmitter can be implemented by integrating an optical filter for performing conversion of frequency modulation-intensity modulation (FM-AM conversion) beyond the second distributed Bragg reflector region 106. The optical filter described above can include a Mach-Zehnder interferometer (MZI) using an optical waveguide with a core including InP and a ring resonator. In addition, it is desirable to appropriately provide a wavelength tuning structure such as a heater to the above-described optical filter. In addition, in order to reduce the connection loss to the optical fiber to which the optical device according to the embodiment is connected, for example, a spot size converter or the like can be integrated beyond the second distributed Bragg reflector region 106.

### Second Embodiment

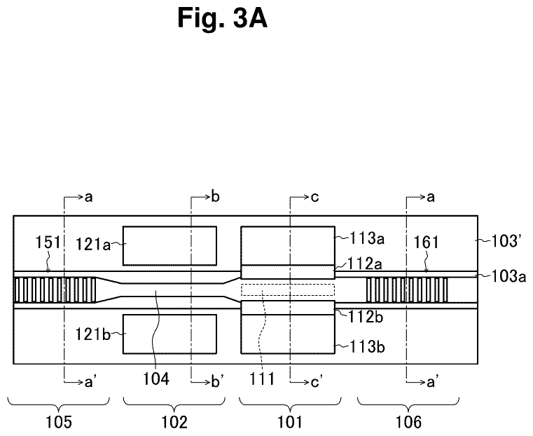

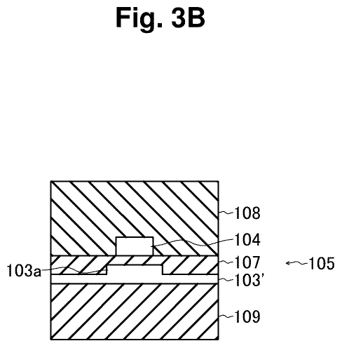

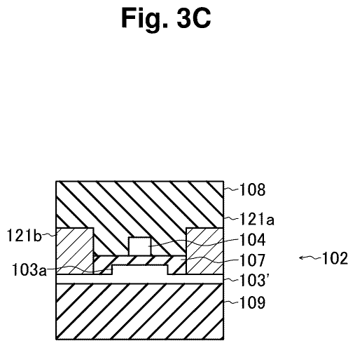

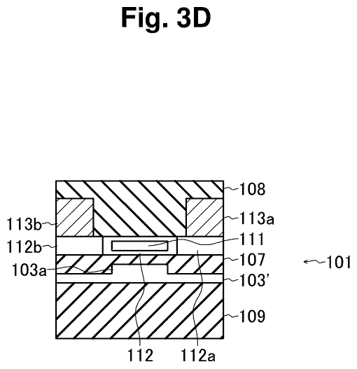

Next, a configuration of an optical device according to a second embodiment of the present invention will be described with reference to FIGS. 3A, 3B, 3C, and 3D. FIG. 3B illustrates a cross section perpendicular to the waveguide direction along line aa′ in FIG. 3A. FIG. 3C illustrates a cross section perpendicular to the waveguide direction along line bb′ in FIG. 3A. FIG. 3D illustrates a cross section perpendicular to the waveguide direction along line cc′ in FIG. 3A. The optical device includes the gain region 101 constituting a waveguide type semiconductor laser, and the waveguide type light modulation region 102 that modulates laser light of the semiconductor laser.

In the second embodiment, in the first embodiment, the semiconductor laser is a distributed Bragg reflector laser, and the gain region 101 is disposed between the first distributed Bragg reflector region 105 and the second distributed Bragg reflector region 106. Further, the light modulation region 102 is disposed between the gain region 101 and the first distributed Bragg reflector region 105.

The gain region 101 includes the p-type semiconductor layer 112a, the i-type semiconductor layer 112, and the n-type semiconductor layer 112b, and the active layer 111 is embedded in the i-type semiconductor layer 112. The p-type semiconductor layer 112a, the i-type semiconductor layer 112, and the n-type semiconductor layer 112b can include, for example, a group III-V compound semiconductor such as InP. By introducing predetermined impurities into the semiconductor layer, the p-type semiconductor layer 112a and the n-type semiconductor layer 112b can be formed. The semiconductor layer in which the p-type semiconductor layer 112a, the i-type semiconductor layer 112, and the n-type semiconductor layer 112b are formed can be formed on a light modulation layer 103′ via the joining layer 107 including SiO₂, for example.

In addition, the active layer 111 can include InGaAlAs. Further, the active layer 111 can have a multiple quantum well structure. A structure is employed in which a current is injected in a direction (lateral direction) intersecting (perpendicular to) the waveguide direction with respect to the i-type semiconductor layer 112 via the p-type semiconductor layer 112a and the n-type semiconductor layer 112b using the p-electrode 113a and the n-electrode 113b (Reference Literature 1).

The light modulation region 102 includes the light modulation layer 103′ including the material having the electro-optical effect and disposed in a range couplable to the propagating light. The frequency of the laser light oscillated by the semiconductor laser is modulated by modulating the effective refractive index of the propagating light mode by applying the modulation electric field to the light modulation layer 103′ using the electrode 121a and the electrode 121b. The light modulation region 102 can include, for example, lithium niobate.

In addition, the light modulation region 102 includes the core 104 formed on the light modulation layer 103′ via the joining layer 107. The core 104 is formed continuously with the i-type semiconductor layer 112 (active layer 111) in the gain region 101. The electrode 121a and the electrode 121b are disposed with the core 104 interposed therebetween. The core 104 can include, for example, a group III-V compound semiconductor such as InP.

The first distributed Bragg reflector region 105 and the second distributed Bragg reflector region 106 include the core 104 formed over the light modulation layer 103′ via the joining layer 107. The core 104 is continuously formed from the light modulation region 102 to the first distributed Bragg reflector region 105. In addition, the core width in the light modulation region 102 is small. Further, in the first distributed Bragg reflector region 105, the diffraction grating 151 is formed on the core 104. Similarly, in the second distributed Bragg reflector region 106, the diffraction grating 161 is formed on the core 104. The diffraction grating 151 and the diffraction grating 161 can also be formed on a side surface of the core 104.

In the second embodiment, the light modulation layer 103′ and the joining layer 107 are formed in common over the entire region of the gain region 101, the light modulation region 102, the first distributed Bragg reflector region 105, and the second distributed Bragg reflector region 106. In addition, the upper cladding layer 108 including, for example, SiO₂ is formed over the entire region of the gain region 101, the light modulation region 102, the first distributed Bragg reflector region 105, and the second distributed Bragg reflector region 106. In addition, the gain region 101 can have a length of 80 μm in the waveguide direction, and the light modulation region 102 can have a length of 40 μm in the waveguide direction. Further, the first distributed Bragg reflector region 105 and the second distributed Bragg reflector region 106 can have a length of 80 μm in the waveguide direction.

The configuration described above is similar to that of the first embodiment described above. In the second embodiment, the light modulation layer 103′ is formed on a lower cladding layer 109 including SiO₂. Furthermore, the light modulation layer 103′ is formed in a rib shape including a rib core 103a protruding to the side where the active layer 111 of the semiconductor laser is formed in a cross-sectional view perpendicular to the propagation direction of the propagating light. A slab portion of the light modulation layer 103′ can have a thickness of 100 nm, and the rib core 103a can have a width of 1000 nm and a height (thickness) of 200 nm. The rib-shaped light modulation layer 103′ is formed over the entire region of the gain region 101, the light modulation region 102, the first distributed Bragg reflector region 105, and the second distributed Bragg reflector region 106.

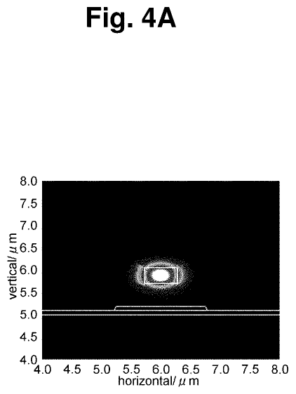

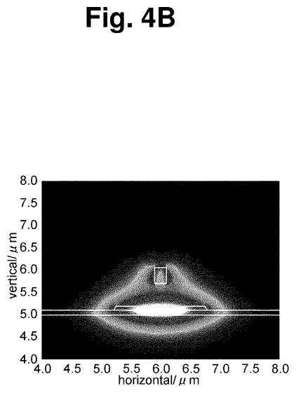

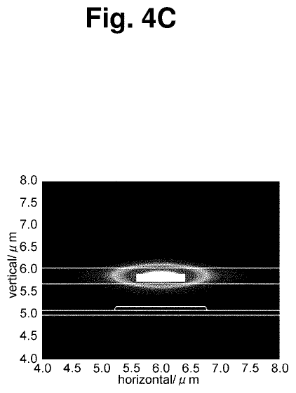

Next, a light propagation mode in the optical device according to the second embodiment will be described with reference to FIGS. 4A, 4B, and 4C.

First, FIG. 4A illustrates a light propagation mode of the first distributed Bragg reflector region 105 (second distributed Bragg reflector region 106). The core 104 in the first distributed Bragg reflector region 105 has a width of 600 nm and a height of 350 nm, and the joining layer 107 has a thickness of 500 nm. Further, the rib core 103a has a width of 1000 nm and a height of 200 nm, and a slab thickness of the light modulation layer 103′ is 100 nm. As illustrated in FIG. 4A, the light is substantially confined in the core 104.

Next, FIG. 4B illustrates a light propagation mode of the light modulation region 102. The core 104 in the light modulation region 102 has a width of 250 nm and a height of 350 nm, and the joining layer 107 has a thickness of 500 nm. Further, the rib core 103a has a width of 1000 nm and a height of 200 nm, and the slab thickness of the light modulation layer 103′ is 100 nm. As illustrated in FIG. 4B, the light is partially confined in the core 104, but most has an intensity distribution in the rib core 103a of the light modulation layer 103′.

In the light modulation region 102, it is important to appropriately adjust the size of the cross section of the core 104 so that the electromagnetic field distribution of the propagating light mode leaks to the rib core 103a. When a modulation electric field is applied from the electrodes 121a and 121b disposed on the left and right of the core 104 (rib core 103a), the refractive index in the rib core 103a is mainly modulated by the electro-optical effect. Thus, the effective refractive index of the propagating light mode in the light modulation region 102 is modulated. The size of the cross section of the core 104, the thickness of the joining layer 107, and the relative positions of the electrode 121a and the electrode 121b with respect to the core 104 are appropriately adjusted so as to obtain an effective refractive index change as large as possible with respect to the applied voltage.

Next, FIG. 4C illustrates a light propagation mode of the gain region 101. The thickness of the semiconductor layer in which the p-type semiconductor layer 112a, the i-type semiconductor layer 112, and the n-type semiconductor layer 112b are formed is 350 nm, the width of the active layer 111 is 800 nm, and the thickness of the active layer 111 is 250 nm. Further, the joining layer 107 had a thickness of 500 nm. As illustrated in FIG. 4C, the light is tightly confined within the active layer 111.

Since the light modulation region 102 (light modulation layer 103′) is made of the material having the electro-optical effect as described above, it is possible to modulate the frequency while suppressing the intensity modulation. Note that, as for the size of the core 104, in consideration of productivity, it is desirable to make the core height (thickness) equal to the thickness of the i-type semiconductor layer 112 in the gain region 101 as described above. It is desirable that the core width is appropriately adjusted in each region so that desired optical confinement in the core 104 is obtained within this condition, and the regions are connected by a tapered structure in which the width is gradually changed so as not to cause optical radiation loss and reflection.

In addition, a small optical transmitter can be implemented by integrating an optical filter for performing conversion of frequency modulation-intensity modulation (FM-AM conversion) beyond the second distributed Bragg reflector region 106. The optical filter described above can include a Mach-Zehnder interferometer (MZI) using an optical waveguide with a core including InP and a ring resonator. In addition, it is desirable to appropriately provide a wavelength tuning structure such as a heater to the above-described optical filter. In addition, in order to reduce the connection loss to the optical fiber to which the optical device according to the embodiment is connected, for example, a spot size converter or the like can be integrated beyond the second distributed Bragg reflector region 106.

### Third Embodiment

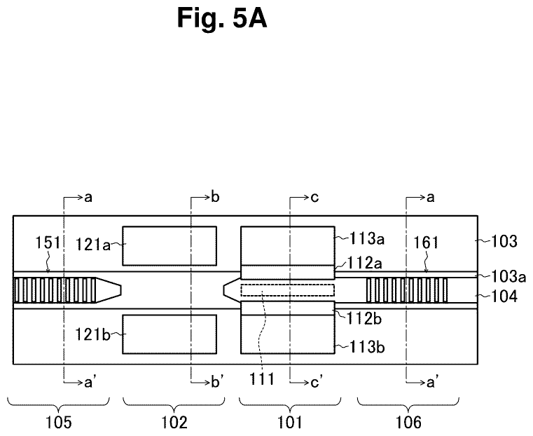

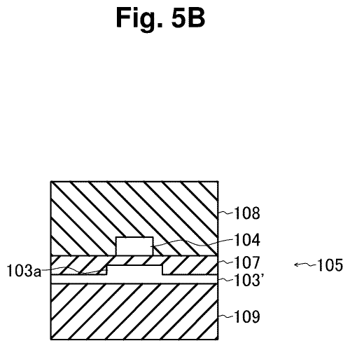

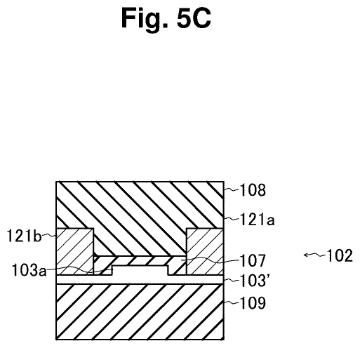

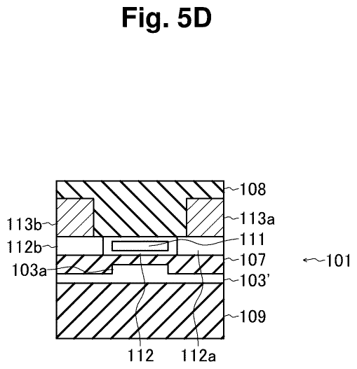

Next, a configuration of an optical device according to a third embodiment of the present invention will be described with reference to FIGS. 5A, 5B, 5C, and 5D. FIG. 5B illustrates a cross section perpendicular to the waveguide direction along line aa′ in FIG. 5A. FIG. 5C illustrates a cross section perpendicular to the waveguide direction along line bb′ in FIG. 5A. FIG. 5D illustrates a cross section perpendicular to the waveguide direction along line cc′ in FIG. 5A. The optical device includes the gain region 101 constituting a waveguide type semiconductor laser, and the waveguide type light modulation region 102 that modulates laser light of the semiconductor laser.

In the third embodiment, the semiconductor laser is a distributed Bragg reflector laser, and the gain region 101 is disposed between the first distributed Bragg reflector region 105 and the second distributed Bragg reflector region 106. Further, the light modulation region 102 is disposed between the gain region 101 and the first distributed Bragg reflector region 105.

The gain region 101 includes the p-type semiconductor layer 112a, the i-type semiconductor layer 112, and the n-type semiconductor layer 112b, and the active layer 111 is embedded in the i-type semiconductor layer 112. The p-type semiconductor layer 112a, the i-type semiconductor layer 112, and the n-type semiconductor layer 112b can include, for example, a group III-V compound semiconductor such as InP. By introducing predetermined impurities into the semiconductor layer, the p-type semiconductor layer 112a and the n-type semiconductor layer 112b can be formed. The semiconductor layer in which the p-type semiconductor layer 112a, the i-type semiconductor layer 112, and the n-type semiconductor layer 112b are formed can be formed on the light modulation layer 103′ via the joining layer 107 including SiO₂, for example.

In addition, the active layer 111 can include InGaAlAs. Further, the active layer 111 can have a multiple quantum well structure. A structure is employed in which a current is injected in a direction (lateral direction) intersecting (perpendicular to) the waveguide direction with respect to the i-type semiconductor layer 112 via the p-type semiconductor layer 112a and the n-type semiconductor layer 112b using the p-electrode 113a and the n-electrode 113b (Reference Literature 1).

The light modulation region 102 includes the light modulation layer 103′ including the material having the electro-optical effect and disposed in a range couplable to the propagating light. The frequency of the laser light oscillated by the semiconductor laser is modulated by modulating the effective refractive index of the propagating light mode by applying the modulation electric field to the light modulation layer 103′ using the electrode 121a and the electrode 121b. The light modulation region 102 can include, for example, lithium niobate.

On the other hand, in the third embodiment, in the light modulation region 102, the core 104 is not formed on the light modulation layer 103′. As described later, the core 104 is formed in the first distributed Bragg reflector region 105 and the second distributed Bragg reflector region 106. The core 104 can include, for example, a group III-V compound semiconductor such as InP.

The first distributed Bragg reflector region 105 and the second distributed Bragg reflector region 106 include the core 104 formed over the light modulation layer 103′ via the joining layer 107. In addition, the core width gradually decreases toward the light modulation region 102. Further, in the first distributed Bragg reflector region 105, the diffraction grating 151 is formed on the core 104. Similarly, in the second distributed Bragg reflector region 106, the diffraction grating 161 is formed on the core 104. The diffraction grating 151 and the diffraction grating 161 can also be formed on a side surface of the core 104.

In the third embodiment, the light modulation layer 103′ and the joining layer 107 are formed in common over the entire region of the gain region 101, the light modulation region 102, the first distributed Bragg reflector region 105, and the second distributed Bragg reflector region 106. In addition, the upper cladding layer 108 including, for example, SiO₂ is formed over the entire region of the gain region 101, the light modulation region 102, the first distributed Bragg reflector region 105, and the second distributed Bragg reflector region 106. In addition, the gain region 101 can have a length of 80 μm in the waveguide direction, and the light modulation region 102 can have a length of 40 μm in the waveguide direction. Further, the first distributed Bragg reflector region 105 and the second distributed Bragg reflector region 106 can have a length of 80 μm in the waveguide direction.

In addition, as in the above-described second embodiment, the light modulation layer 103′ is formed on the lower cladding layer 109 including SiO₂. Furthermore, the light modulation layer 103′ is formed in a rib shape including the rib core 103a protruding to the side where the active layer 111 of the semiconductor laser is formed in a cross-sectional view perpendicular to the propagation direction of the propagating light. A slab portion of the light modulation layer 103′ can have a thickness of 100 nm, and the rib core 103a can have a width of 1000 nm and a height (thickness) of 200 nm. The rib-shaped light modulation layer 103′ is formed over the entire region of the gain region 101, the light modulation region 102, the first distributed Bragg reflector region 105, and the second distributed Bragg reflector region 106.

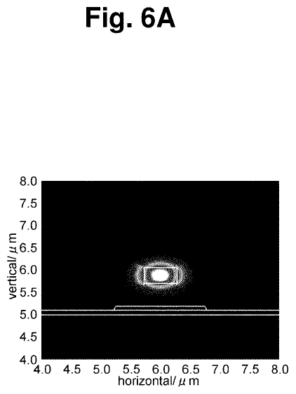

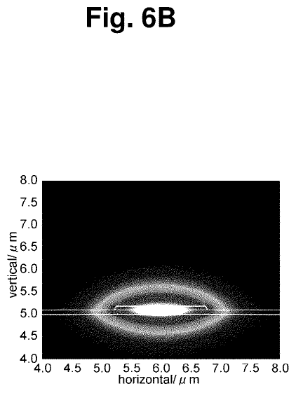

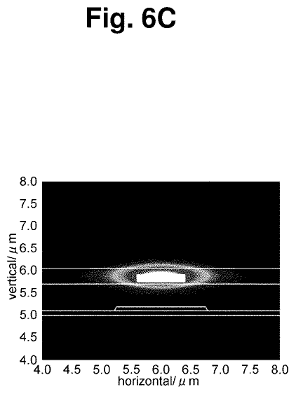

Next, a light propagation mode in the optical device according to the third embodiment will be described with reference to FIGS. 6A, 6B, and 6C.

First, FIG. 6A illustrates a light propagation mode of the first distributed Bragg reflector region 105 (second distributed Bragg reflector region 106). The core 104 in the first distributed Bragg reflector region 105 has a width of 600 nm and a height of 350 nm, and the joining layer 107 has a thickness of 500 nm. Further, the rib core 103a has a width of 1000 nm and a height of 200 nm, and the slab thickness of the light modulation layer 103′ is 100 nm. As illustrated in FIG. 6A, the light is substantially confined in the core 104.

Next, FIG. 6B illustrates a light propagation mode of the light modulation region 102 in which the core 104 is not formed. The rib core 103a in the light modulation region 102 has a width of 1000 nm and a height of 200 nm, and the slab thickness of the light modulation layer 103′ is 100 nm. As illustrated in FIG. 6B, the light is confined in the rib core 103a of the light modulation layer 103′, and almost all of the light has an intensity distribution in the rib core 103a of the light modulation layer 103′.

In the light modulation region 102, it is important that the electromagnetic field distribution of the propagating light mode exists in the rib core 103a. When a modulation electric field is applied from the electrodes 121a and 121b disposed on the left and right of the rib core 103a, the refractive index in the rib core 103a is mainly modulated by the electro-optical effect. Thus, the effective refractive index of the propagating light mode in the light modulation region 102 is modulated.

Next, FIG. 6C illustrates a light propagation mode of the gain region 101. The thickness of the semiconductor layer in which the p-type semiconductor layer 112a, the i-type semiconductor layer 112, and the n-type semiconductor layer 112b are formed is 350 nm, the width of the active layer 111 is 800 nm, and the thickness of the active layer 111 is 250 nm. Further, the joining layer 107 had a thickness of 500 nm. As illustrated in FIG. 6C, the light is tightly confined within the active layer 111.

Since the light modulation region 102 (light modulation layer 103′) is made of the material having the electro-optical effect as described above, it is possible to modulate the frequency while suppressing the intensity modulation. Further, by not providing the core 104 in the light modulation region 102, further light can be confined in the rib core 103a.

In addition, a small optical transmitter can be implemented by integrating an optical filter for performing conversion of frequency modulation-intensity modulation (FM-AM conversion) beyond the second distributed Bragg reflector region 106. The optical filter described above can include a Mach-Zehnder interferometer (MZI) using an optical waveguide with a core including InP and a ring resonator. In addition, it is desirable to appropriately provide a wavelength tuning structure such as a heater to the above-described optical filter. In addition, in order to reduce the connection loss to the optical fiber to which the optical device according to the embodiment is connected, for example, a spot size converter or the like can be integrated beyond the second distributed Bragg reflector region 106.

### Fourth Embodiment

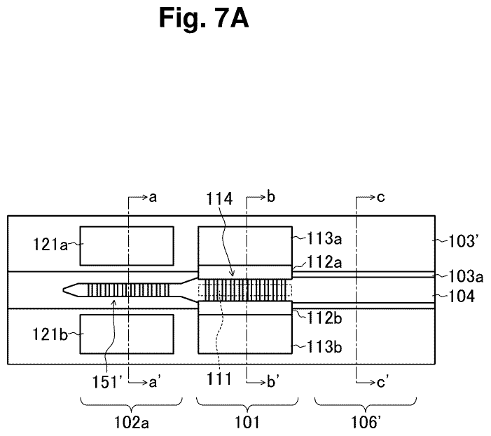

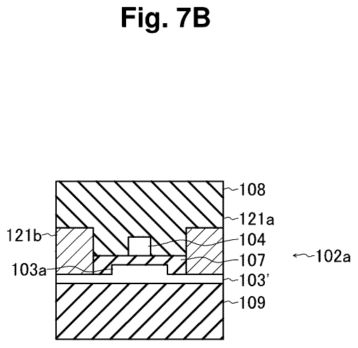

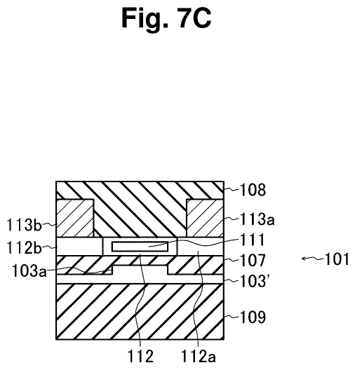

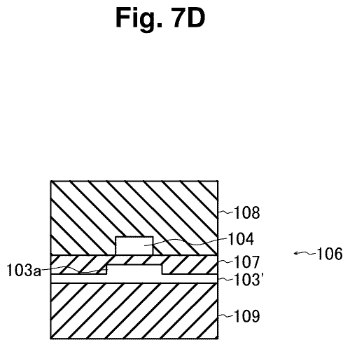

Next, a configuration of an optical device according to a fourth embodiment of the present invention will be described with reference to FIGS. 7A, 7B, 7C, and 7D. FIG. 7B illustrates a cross section perpendicular to the waveguide direction along line aa′ in FIG. 7A. FIG. 7C illustrates a cross section perpendicular to the waveguide direction along line bb′ in FIG. 7A. FIG. 7D illustrates a cross section perpendicular to the waveguide direction along line cc′ in FIG. 7A. The optical device includes the gain region 101 constituting a waveguide type semiconductor laser, and a waveguide type light modulation region 102a that modulates laser light of the semiconductor laser.

In the fourth embodiment, the semiconductor laser is a distributed feedback (DFB) laser, and includes a diffraction grating 114 in the gain region 101.

The gain region 101 includes the p-type semiconductor layer 112a, the i-type semiconductor layer 112, and the n-type semiconductor layer 112b, and the active layer 111 is embedded in the i-type semiconductor layer 112. In the i-type semiconductor layer 112, the diffraction grating 114 can be formed on the active layer 111. The p-type semiconductor layer 112a, the i-type semiconductor layer 112, and the n-type semiconductor layer 112b can include, for example, a group III-V compound semiconductor such as InP. By introducing predetermined impurities into the semiconductor layer, the p-type semiconductor layer 112a and the n-type semiconductor layer 112b can be formed. The semiconductor layer in which the p-type semiconductor layer 112a, the i-type semiconductor layer 112, and the n-type semiconductor layer 112b are formed can be formed on the light modulation layer 103′ via the joining layer 107 including SiO₂, for example.

In addition, the active layer 111 can include InGaAlAs. Further, the active layer 111 can have a multiple quantum well structure. A structure is employed in which a current is injected in a direction (lateral direction) intersecting (perpendicular to) the waveguide direction with respect to the i-type semiconductor layer 112 via the p-type semiconductor layer 112a and the n-type semiconductor layer 112b using the p-electrode 113a and the n-electrode 113b (Reference Literature 1).

The light modulation region 102a includes the light modulation layer 103′ including the material having the electro-optical effect, and disposed in a range couplable to the propagating light. The frequency of the laser light oscillated by the semiconductor laser is modulated by modulating the effective refractive index of the propagating light mode by applying the modulation electric field to the light modulation layer 103′ using the electrode 121a and the electrode 121b. The light modulation region 102a can include, for example, lithium niobate.

Furthermore, in the fourth embodiment, in the light modulation region 102a, the diffraction grating 151′ is provided in the core 104 formed on the light modulation layer 103′ via the joining layer 107, and a distributed Bragg reflection structure is provided in the light modulation region 102a. The diffraction grating 151′ can be formed on a top or side surface of the core 104. In the fourth embodiment, the light modulation region 102a also constitutes a distributed Bragg reflector region. The core 104 is formed continuously with the i-type semiconductor layer 112 (active layer 111) in the gain region 101. The electrode 121a and the electrode 121b are disposed with the core 104 interposed therebetween. The core 104 can include, for example, a group III-V compound semiconductor such as InP.

In the fourth embodiment, the diffraction grating 114 of the gain region 101 is designed to have an appropriate detuning amount between the diffraction grating 114 and the light modulation region 102a that also constitutes the distributed Bragg reflector region.

In the fourth embodiment, an output optical waveguide 106′ is formed at a subsequent stage of the gain region 101. The output optical waveguide 106′ includes the core 104 formed over the light modulation layer 103′ via the joining layer 107. The core 104 is formed continuously with the i-type semiconductor layer 112 (active layer 111) in the gain region 101.

In the fourth embodiment, the light modulation layer 103′ and the joining layer 107 are formed in common over the entire region of the gain region 101, the light modulation region 102a, and the output optical waveguide 106′. In addition, the upper cladding layer 108 including, for example, SiO₂ is formed over the entire region of the gain region 101, the light modulation region 102a, and the output optical waveguide 106′. Furthermore, the gain region 101 can have a length of 80 μm in the waveguide direction, and the light modulation region 102a can have a length of 40 μm in the waveguide direction. In addition, the length of the output optical waveguide 106′ in the waveguide direction can be 80 μm.

In addition, as in the above-described second embodiment, the light modulation layer 103′ is formed on the lower cladding layer 109 including SiO₂. Furthermore, the light modulation layer 103′ is formed in a rib shape including the rib core 103a protruding to the side where the active layer 111 of the semiconductor laser is formed in a cross-sectional view perpendicular to the propagation direction of the propagating light. A slab portion of the light modulation layer 103′ can have a thickness of 100 nm, and the rib core 103a can have a width of 1000 nm and a height (thickness) of 200 nm. The rib-shaped light modulation layer 103′ is formed over the entire region of the gain region 101, the light modulation region 102a, and the output optical waveguide 106′.

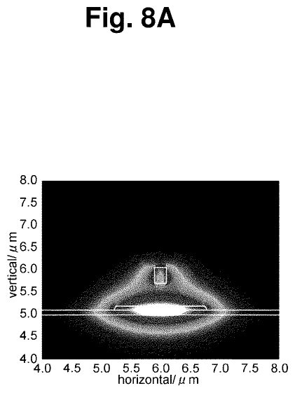

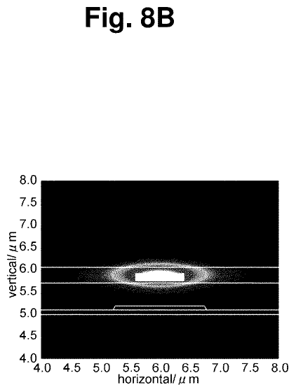

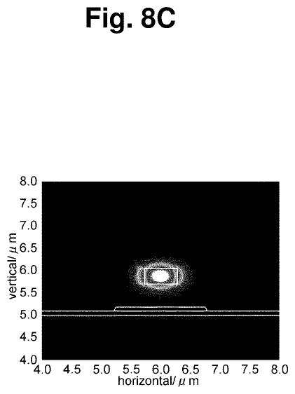

Next, a light propagation mode in the optical device according to the fourth embodiment will be described with reference to FIGS. 8A, 8B, and 8C.

First, FIG. 8A illustrates a light propagation mode of the light modulation region 102a. The core 104 in the light modulation region 102 has a width of 250 nm and a height of 350 nm, and the joining layer 107 has a thickness of 500 nm. Further, the rib core 103a has a width of 1000 nm and a height of 200 nm, and the slab thickness of the light modulation layer 103′ is 100 nm. As illustrated in FIG. 8A, almost all of the light is confined in the rib core 103a of the light modulation layer 103′.

In the light modulation region 102a, it is important to appropriately adjust the size of the cross section of the core 104 so that the electromagnetic field distribution of the propagating light mode leaks to the light modulation layer 103 (rib core 103a) and the electromagnetic field distribution of the propagating light mode exists in the rib core 103a. When the modulation electric field is applied from the electrodes 121a and 121b disposed on the left and right of the core 104 (rib core 103a), the refractive index in the rib core 103a is mainly modulated by the electro-optical effect. Thus, the effective refractive index of the propagating light mode in the light modulation region 102a is modulated.

Next, FIG. 8B illustrates a light propagation mode of the gain region 101. The thickness of the semiconductor layer in which the p-type semiconductor layer 112a, the i-type semiconductor layer 112, and the n-type semiconductor layer 112b are formed is 350 nm, the width of the active layer 111 is 800 nm, and the thickness of the active layer 111 is 100 nm. Further, the joining layer 107 had a thickness of 500 nm. As illustrated in FIG. 8B, the light is tightly confined within the active layer 111.

Next, FIG. 8C illustrates a light propagation mode of the output optical waveguide 106′. The core 104 in the output optical waveguide 106′ has a width of 550 nm and a height of 350 nm, and the joining layer 107 has a thickness of 500 nm. Further, the rib core 103a has a width of 1000 nm and a height of 200 nm, and the slab thickness of the light modulation layer 103′ is 100 nm. As illustrated in FIG. 8C, the light is substantially confined in the core 104.

Since the light modulation region 102a (light modulation layer 103′) is made of the material having the electro-optical effect as described above, it is possible to modulate the frequency while suppressing the intensity modulation.

Note that, as for the size of the core 104, in consideration of productivity, it is desirable to make the core height (thickness) equal to the thickness of the i-type semiconductor layer 112 in the gain region 101 as described above. It is desirable that the core width is appropriately adjusted in each region so that desired optical confinement in the core 104 is obtained within this condition, and the regions are connected by a tapered structure in which the width is gradually changed so as not to cause optical radiation loss and reflection.

In addition, a small optical transmitter can be implemented by integrating an optical filter for performing conversion of frequency modulation-intensity modulation (FM-AM conversion) before the output optical waveguide 106′. The optical filter described above can include a Mach-Zehnder interferometer (MZI) using an optical waveguide with a core including InP and a ring resonator. In addition, it is desirable to appropriately provide a wavelength tuning structure such as a heater to the above-described optical filter. In addition, in order to reduce the connection loss to the optical fiber to which the optical device according to the embodiment is connected, for example, a spot size converter or the like can be integrated at the tip of the output optical waveguide 106′.

### Fifth Embodiment

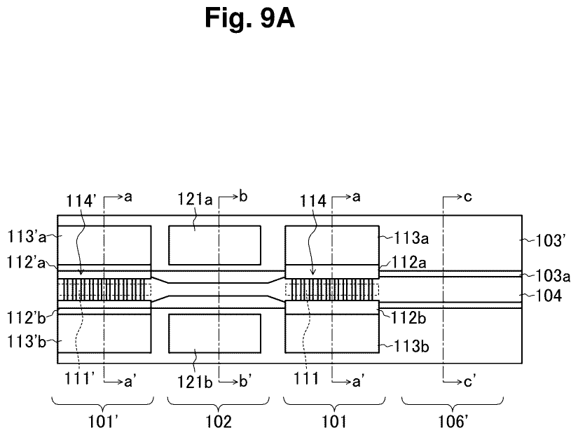

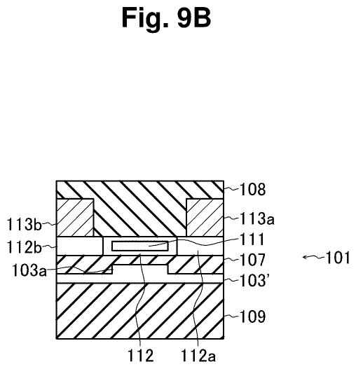

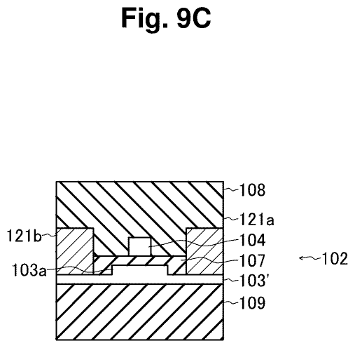

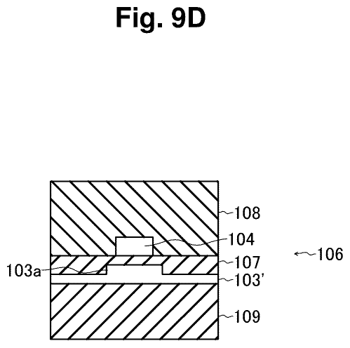

Next, a configuration of an optical device according to a fifth embodiment of the present invention will be described with reference to FIGS. 9A, 9B, 9C, and 9D. FIG. 9B illustrates a cross section perpendicular to the waveguide direction along line aa′ in FIG. 9A. FIG. 9C illustrates a cross section perpendicular to the waveguide direction along line bb′ in FIG. 9A. FIG. 9D illustrates a cross section perpendicular to the waveguide direction along line cc′ in FIG. 9A. The optical device includes the gain region 101 constituting a waveguide type semiconductor laser, and the waveguide type light modulation region 102 that modulates laser light of the semiconductor laser.

In the fifth embodiment, the semiconductor laser is a distributed feedback (DFB) laser, and includes the diffraction grating 114 in the gain region 101. Furthermore, in addition to the gain region 101, a gain region 101′ is provided (with two gain regions).

The gain region 101 includes the p-type semiconductor layer 112a, the i-type semiconductor layer 112, and the n-type semiconductor layer 112b, and the active layer 111 is embedded in the i-type semiconductor layer 112. In the i-type semiconductor layer 112, the diffraction grating 114 can be formed on the active layer 111. The p-type semiconductor layer 112a, the i-type semiconductor layer 112, and the n-type semiconductor layer 112b can include, for example, a group III-V compound semiconductor such as InP. By introducing predetermined impurities into the semiconductor layer, the p-type semiconductor layer 112a and the n-type semiconductor layer 112b can be formed. The semiconductor layer in which the p-type semiconductor layer 112a, the i-type semiconductor layer 112, and the n-type semiconductor layer 112b are formed can be formed on the light modulation layer 103′ via the joining layer 107 including SiO₂, for example.

In addition, the active layer 111 can include InGaAlAs. Further, the active layer 111 can have a multiple quantum well structure. A structure is employed in which a current is injected in a direction (lateral direction) intersecting (perpendicular to) the waveguide direction with respect to the i-type semiconductor layer 112 via the p-type semiconductor layer 112a and the n-type semiconductor layer 112b using the p-electrode 113a and the n-electrode 113b (Reference Literature 1).

The gain region 101′ also has a configuration similar to that of the gain region 101 described above. Between the two gain regions 101 and 101′, each diffraction grating can be designed to have an appropriate amount of detuning.

The light modulation region 102 includes the light modulation layer 103′ including the material having the electro-optical effect and disposed in a range couplable to the propagating light. The frequency of the laser light oscillated by the semiconductor laser is modulated by modulating the effective refractive index of the propagating light mode by applying the modulation electric field to the light modulation layer 103′ using the electrode 121a and the electrode 121b. The light modulation region 102 can include, for example, lithium niobate. In the fifth embodiment, the light modulation region 102 is disposed between the two gain regions 101 and 101′.

In addition, the light modulation region 102 includes the core 104 formed on the light modulation layer 103′ via the joining layer 107. The core 104 is formed continuously with the i-type semiconductor layer 112 (active layer 111) in the gain region 101. The electrode 121a and the electrode 121b are disposed with the core 104 interposed therebetween. The core 104 can include, for example, a group III-V compound semiconductor such as InP.

In the fifth embodiment, the output optical waveguide 106′ is formed at the subsequent stage of the gain region 101. The output optical waveguide 106′ includes the core 104 formed over the light modulation layer 103′ via the joining layer 107. The core 104 is formed continuously with the i-type semiconductor layer 112 (active layer 111) in the gain region 101.

n the fifth embodiment, the light modulation layer 103′ and the joining layer 107 are formed in common over the entire region of the gain region 101, the light modulation region 102, the gain region 101′, and the output optical waveguide 106′. In addition, the upper cladding layer 108 including SiO₂, for example, is formed over the entire region of the gain region 101, the gain region 101′, the light modulation region 102, and the output optical waveguide 106′. Furthermore, the gain region 101 and the gain region 101′ can have a length of 80 μm in the waveguide direction, and the light modulation region 102 can have a length of 40 μm in the waveguide direction. In addition, the length of the output optical waveguide 106′ in the waveguide direction can be 80 μm.

In addition, as in the above-described second embodiment, the light modulation layer 103′ is formed on the lower cladding layer 109 including SiO₂. Furthermore, the light modulation layer 103′ is formed in a rib shape including the rib core 103a protruding to the side where the active layer 111 of the semiconductor laser is formed in a cross-sectional view perpendicular to the propagation direction of the propagating light. A slab portion of the light modulation layer 103′ can have a thickness of 100 nm, and the rib core 103a can have a width of 1000 nm and a height (thickness) of 200 nm. The rib-shaped light modulation layer 103′ is formed over the entire region of the gain region 101, the light modulation region 102, and the output optical waveguide 106′.

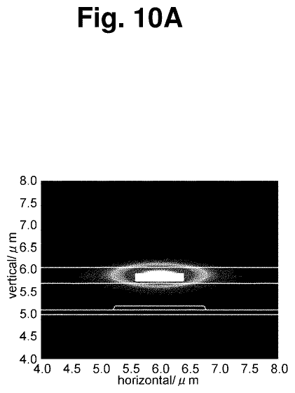

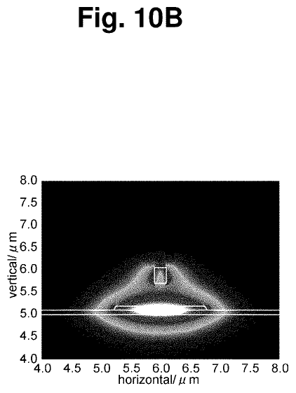

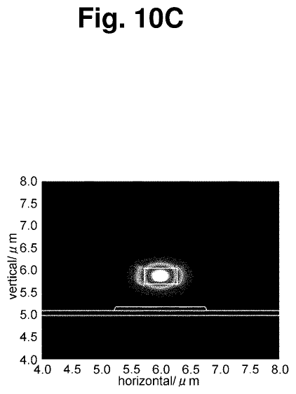

Next, a light propagation mode in the optical device according to the fifth embodiment will be described with reference to FIGS. 10A, 10B, and 10C.

First, FIG. 10A illustrates a light propagation mode of the gain region 101. The thickness of the semiconductor layer in which the p-type semiconductor layer 112a, the i-type semiconductor layer 112, and the n-type semiconductor layer 112b are formed is 350 nm, the width of the active layer 111 is 800 nm, and the thickness of the active layer 111 is 100 nm. Further, the joining layer 107 had a thickness of 500 nm. Further, the rib core 103a has a width of 1000 nm and a height of 200 nm, and the slab thickness of the light modulation layer 103′ is 100 nm. As illustrated in FIG. 10A, the light is tightly confined within the active layer 111.

Next, FIG. 10B illustrates a light propagation mode of the light modulation region 102. The core 104 in the light modulation region 102 has a width of 250 nm and a height of 350 nm, and the joining layer 107 has a thickness of 500 nm. Further, the rib core 103a has a width of 1000 nm and a height of 200 nm, and the slab thickness of the light modulation layer 103′ is 100 nm. As illustrated in FIG. 10B, almost all of the light is confined in the rib core 103a of the light modulation layer 103′.

In the light modulation region 102, it is important that the electromagnetic field distribution of the propagating light mode exists in the rib core 103a. When the modulation electric field is applied from the electrodes 121a and 121b disposed on the left and right of the rib core 103a, the refractive index in the rib core 103a is mainly modulated by the electro-optical effect. Thus, the effective refractive index of the propagating light mode in the light modulation region 102 is modulated.

Next, FIG. 10C illustrates a light propagation mode of the output optical waveguide 106′. The core 104 in the output optical waveguide 106′ has a width of 550 nm and a height of 350 nm, and the joining layer 107 has a thickness of 500 nm. Further, the rib core 103a has a width of 1000 nm and a height of 200 nm, and the slab thickness of the light modulation layer 103′ is 100 nm. As illustrated in FIG. 10C, the light is substantially confined in the core 104.

Since the light modulation region 102 (light modulation layer 103′) is made of the material having the electro-optical effect as described above, it is possible to modulate the frequency while suppressing the intensity modulation.

Note that, as for the size of the core 104, in consideration of productivity, it is desirable to make the core height (thickness) equal to the thickness of the i-type semiconductor layer 112 in the gain region 101 as described above. It is desirable that the core width is appropriately adjusted in each region so that desired optical confinement in the core 104 is obtained within this condition, and the regions are connected by a tapered structure in which the width is gradually changed so as not to cause optical radiation loss and reflection.

In addition, a small optical transmitter can be implemented by integrating an optical filter for performing conversion of frequency modulation-intensity modulation (FM-AM conversion) before the output optical waveguide 106′. The optical filter described above can include a Mach-Zehnder interferometer (MZI) using an optical waveguide with a core including InP and a ring resonator. In addition, it is desirable to appropriately provide a wavelength tuning structure such as a heater to the above-described optical filter. In addition, in order to reduce the connection loss to the optical fiber to which the optical device according to the embodiment is connected, for example, a spot size converter or the like can be integrated at the tip of the output optical waveguide 106′.

### Sixth Embodiment

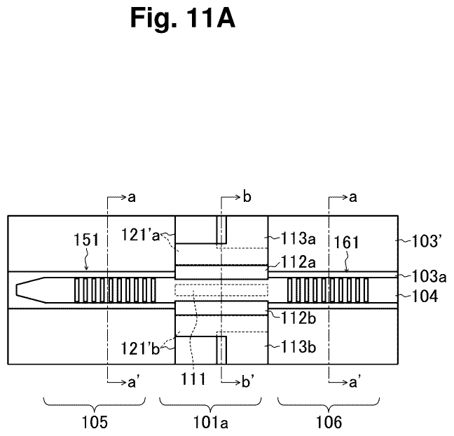

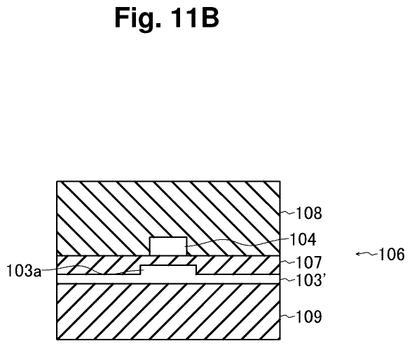

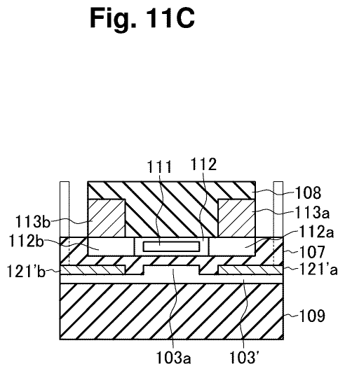

Next, a configuration of an optical device according to a sixth embodiment of the present invention will be described with reference to FIGS. 11A, 11B, and 11C. FIG. 11B illustrates a cross section perpendicular to the waveguide direction along line aa′ in FIG. 11A. FIG. 11C illustrates a cross section perpendicular to the waveguide direction along line bb′ in FIG. 11A. The optical device includes a gain region and light modulation region 101a constituting a waveguide type semiconductor laser as well as a waveguide type light modulation region that modulates laser light of the semiconductor laser. In this optical device, the light modulation region is disposed to overlap with the gain region.

In the sixth embodiment, the semiconductor laser is a distributed Bragg reflector laser, and the gain region and light modulation region 101a is disposed between the first distributed Bragg reflector region 105 and the second distributed Bragg reflector region 106.

The gain region and light modulation region 101a includes the p-type semiconductor layer 112a, the i-type semiconductor layer 112, and the n-type semiconductor layer 112b, and the active layer 111 is embedded in the i-type semiconductor layer 112. The p-type semiconductor layer 112a, the i-type semiconductor layer 112, and the n-type semiconductor layer 112b can include, for example, a group III-V compound semiconductor such as InP. By introducing predetermined impurities into the semiconductor layer, the p-type semiconductor layer 112a and the n-type semiconductor layer 112b can be formed.

In addition, the active layer 111 can include InGaAlAs. Further, the active layer 111 can have a multiple quantum well structure. A structure is employed in which a current is injected in a direction (lateral direction) intersecting (perpendicular to) the waveguide direction with respect to the i-type semiconductor layer 112 via the p-type semiconductor layer 112a and the n-type semiconductor layer 112b using the p-electrode 113a and the n-electrode 113b (Reference Literature 1).

In addition, the gain region and light modulation region 101a includes the light modulation layer 103′ including the material having the electro-optical effect and disposed in a range couplable to the propagating light. In the gain region and light modulation region 101a, the semiconductor layer in which the p-type semiconductor layer 112a, the i-type semiconductor layer 112, and the n-type semiconductor layer 112b are formed is formed on the light modulation layer 103′ via the joining layer 107 including SiO₂.

The light modulation layer 103′ in the gain region and light modulation region 101a is connected to an electrode 121′a and an electrode 121′b taken out to an upper side outside the formation region of the p-type semiconductor layer 112a, the i-type semiconductor layer 112, and the n-type semiconductor layer 112b. The frequency of the laser light oscillated by the semiconductor laser is modulated by modulating the effective refractive index of the propagating light mode by applying the modulation electric field to the light modulation layer 103′ by the electrode 121′a and the electrode 121′b. The light modulation region 102 can include, for example, lithium niobate.

The first distributed Bragg reflector region 105 and the second distributed Bragg reflector region 106 include the core 104 formed over the light modulation layer 103′ via the joining layer 107. The core 104 is formed continuously with the i-type semiconductor layer 112. Further, in the first distributed Bragg reflector region 105, the diffraction grating 151 is formed on the core 104. Similarly, in the second distributed Bragg reflector region 106, the diffraction grating 161 is formed on the core 104. The diffraction grating 151 and the diffraction grating 161 can also be formed on a side surface of the core 104.

In the sixth embodiment, the light modulation layer 103′ and the joining layer 107 are formed in common over the entire region of the first distributed Bragg reflector region 105, the gain region and light modulation region 101a, and the second distributed Bragg reflector region 106. In addition, the upper cladding layer 108 including, for example, SiO₂ is formed over the entire region of the first distributed Bragg reflector region 105, the gain region and light modulation region 101a, and the second distributed Bragg reflector region 106. Further, the gain region and light modulation region 101a can have a length of 40 μm in the waveguide direction, and the first distributed Bragg reflector region 105 and the second distributed Bragg reflector region 106 can have a length of 80 μm in the waveguide direction.

Further, the light modulation layer 103′ is formed on the lower cladding layer 109 including SiO₂. Furthermore, the light modulation layer 103′ is formed in a rib shape including the rib core 103a protruding to the side where the active layer 111 of the semiconductor laser is formed in a cross-sectional view perpendicular to the propagation direction of the propagating light. A slab portion of the light modulation layer 103′ can have a thickness of 100 nm, and the rib core 103a can have a width of 1000 nm and a height (thickness) of 200 nm. The rib-shaped light modulation layer 103′ is formed over the entire region of the first distributed Bragg reflector region 105, the gain region and light modulation region 101a, and the second distributed Bragg reflector region 106.

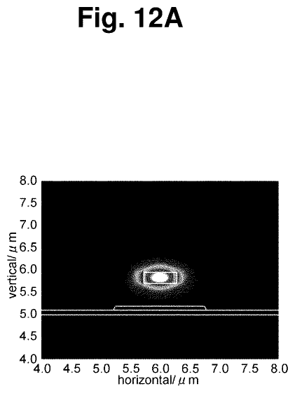

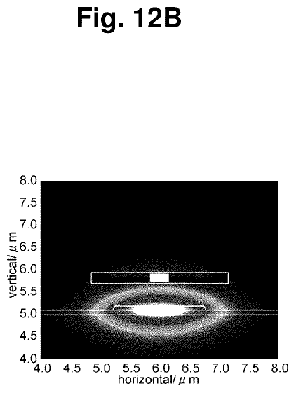

Next, a light propagation mode in the optical device according to the sixth embodiment will be described with reference to FIGS. 12A and 12B.

First, FIG. 12A illustrates a light propagation mode of the first distributed Bragg reflector region 105 (second distributed Bragg reflector region 106). The core 104 in the first distributed Bragg reflector region 105 has a width of 550 nm and a height of 250 nm, and the joining layer 107 has a thickness of 500 nm. Further, the rib core 103a has a width of 1000 nm and a height of 200 nm, and the slab thickness of the light modulation layer 103′ is 100 nm. As illustrated in FIG. 12A, the light is substantially confined in the core 104.

Next, FIG. 12B illustrates a light propagation mode of the gain region and light modulation region 101a. In the gain region and light modulation region 101a, the light mode exists in both the rib core 103a and the active layer 111, and it is important to obtain the light gain and obtain refractive index modulation. When a modulation electric field is applied from the electrode 121′a and the electrode 121′b disposed on the left and right of the rib core 103a, the refractive index in the rib core 103a is mainly modulated by the electro-optical effect. Thus, the effective refractive index of the propagating light mode in the gain region and light modulation region 101a is modulated. The size of the cross-section of the rib core 103a, the thickness of the joining layer 107, and the relative positions of the electrode 121′a and the electrode 121′b with respect to the core 104 are appropriately adjusted so as to obtain an effective refractive index change as large as possible with respect to the applied voltage.

The thickness of the semiconductor layer in which the p-type semiconductor layer 112a, the i-type semiconductor layer 112, and the n-type semiconductor layer 112b are formed is 250 nm, the width of the active layer 111 is 300 nm, and the thickness of the active layer 111 is 250 nm. Further, the joining layer 107 had a thickness of 500 nm. Further, the rib core 103a has a width of 1000 nm and a height of 200 nm, and the slab thickness of the light modulation layer 103′ is 100 nm. As illustrated in FIG. 12B, the light is mainly confined in the rib core 103a and is also present in the active layer 111, so that a light gain can be obtained.

Since the light modulation layer 103′ is made of the material having the electro-optical effect as described above, it is possible to modulate the frequency while suppressing the intensity modulation. Note that, as for the size of the core 104, in consideration of productivity, it is desirable to make the core height (thickness) equal to the thickness of the i-type semiconductor layer 112 as described above.

In addition, a small optical transmitter can be implemented by integrating an optical filter for performing conversion of frequency modulation-intensity modulation (FM-AM conversion) beyond the second distributed Bragg reflector region 106. The optical filter described above can include a Mach-Zehnder interferometer (MZI) using an optical waveguide with a core including InP and a ring resonator. In addition, it is desirable to appropriately provide a wavelength tuning structure such as a heater to the above-described optical filter. In addition, in order to reduce the connection loss to the optical fiber to which the optical device according to the embodiment is connected, for example, a spot size converter or the like can be integrated beyond the second distributed Bragg reflector region 106.

According to the present invention, since the light modulation region is made of the material having the electro-optical effect as described above, it is possible to modulate the frequency while suppressing the intensity modulation.

Note that the present invention is not limited to the above-described embodiment, and it is apparent that various modifications and combinations can be implemented by those skilled in the art without departing from the technical spirit of the present invention.

### REFERENCE SIGNS LIST

101 Gain region
102 Light modulation region
103 Light modulation layer

### 104 Core

105 First distributed Bragg reflector region
106 Second distributed Bragg reflector region
107 Joining layer
108 Upper cladding layer
111 Active layer
112a p-type semiconductor layer
112b n-type semiconductor layer
113a p-electrode
113b n-electrode

### 121a, 121b Electrode

151 Diffraction grating
161 Diffraction grating

1. An optical device, comprising:
a gain region constituting a waveguide type semiconductor laser; and
a waveguide type light modulation region that modulates laser light of the semiconductor laser, wherein
the light modulation region includes a light modulation layer made of a material having an electro-optical effect and disposed in a range couplable to propagating light, the light modulation layer configured to modulate a frequency of laser light oscillated by the semiconductor laser by modulating an effective refractive index of a propagating light mode by applying a modulation electric field to the light modulation layer.

2. The optical device according to claim 1, wherein
the semiconductor laser is a distributed Bragg reflector laser, and
the light modulation region is disposed between the gain region and a distributed Bragg reflector region.

3. The optical device according to claim 2, wherein
the light modulation layer has a rib shape protruding to a side where an active layer of the semiconductor laser is formed in a cross-sectional view perpendicular to a propagation direction of propagating light.

4. The optical device according to claim 3, further comprising:
a core formed in an active layer of the gain region continuously over the light modulation region and a distributed Bragg reflector region continuous to the light modulation region.

5. The optical device according to claim 1, wherein
the light modulation region is disposed to overlap with the gain region.

6. The optical device according to claim 1, wherein
the semiconductor laser is a distributed feedback laser.

7. The optical device according to claim 6, further comprising:
two of the gain regions, wherein
the light modulation region is disposed between the two gain regions.

8. The optical device according to claim 6, wherein
the light modulation region includes a distributed Bragg reflection structure.

9. The optical device according to claim 5, wherein the semiconductor laser is a distributed Bragg reflector laser.

10. The optical device according to claim 5, wherein the light modulation layer has a rib shape protruding to a side where an active layer of the semiconductor laser is formed in a cross-sectional view perpendicular to a propagation direction of propagating light.

11. The optical device according to claim 10, wherein the light modulation layer has a rib shape protruding to a side where an active layer of the semiconductor laser is formed in a cross-sectional view perpendicular to a propagation direction of propagating light.
